(19) United States
(12) Patent Application Publication
(10) Pub. No.: US 2014/0060937 A1
(43) Pub. Date: Mar. 6, 2014

(54) POLYCRYSTALLINE DIAMOND COMPACT COATED WITH HIGH ABRASION RESISTANCE DIAMOND LAYERS

(71) Applicants: Valeriy V. Konovalov, Lewis Center, OH (US); Ram Raghavan, Galena, OH (US)

(72) Inventors: Valeriy V. Konovalov, Lewis Center, OH (US); Ram Raghavan, Galena, OH (US)

(73) Assignee: Diamond Innovations, Inc., Worthington, OH (US)

(21) Appl. No.: 13/602,083

(22) Filed: Aug. 31, 2012

(51) Int. Cl. E21B 10/46; C23C 16/27

(52) U.S. Cl. 175/428; 427/534

(57) ABSTRACT

A cutting element may comprise a substrate, a first polycrystalline diamond volume, and a second diamond or diamond like volume. The first polycrystalline diamond volume may contain a catalyst material. The first polycrystalline diamond volume may be bonded to the substrate. The second diamond or diamond like volume may be formed predominantly from carbon atoms and free of catalyst materials. The second diamond or diamond like volume may be adjacent to a working surface of cutting element. The second diamond or diamond like volume may be bonded to the first polycrystalline diamond volume.

### BACKGROUND OF THE INVENTION

The present disclosure relates to polycrystalline diamond materials, and, more specifically, to polycrystalline composites and compacts, coated with high abrasion resistance diamond layers.

Polycrystalline diamond composite (or “PDC”, as used hereafter) may represent a volume of crystalline diamond grains with embedded foreign material filling the inter-grain space. In one particular case, composite comprises crystalline diamond grains, bonded to each other by strong diamond-to-diamond bonds and forming a rigid polycrystalline diamond body, and the inter-grain regions, disposed between the bonded grains and filled with a catalyst material (e.g. cobalt or its alloys), which was used to promote diamond bonding during fabrication. Suitable metal solvent catalysts may include the metal in Group VIII of the Periodic table. PDC cutting element (or “PDC cutter”, as is used thereafter) comprises an above mentioned polycrystalline diamond body attached to a suitable support substrate, e.g. cobalt cemented tungsten carbide (WC—Co), by the virtue of the presence of cobalt metal. In another particular case, polycrystalline diamond composite comprises a plurality of crystalline diamond grains, which are not bonded to each other, but instead are binded together by foreign bonding materials such as borides, nitrides, carbides, etc. (e.g. SiC).

Polycrystalline diamond composites and PDC cutters can be fabricated in different ways and the following examples do not limit a variety of different types of diamond composites and PDC cutters which can be coated according to this invention. In one example, PDC cutters are formed by placing a mixture of diamond polycrystalline powder with a suitable solvent catalyst material (e.g. cobalt) on the top of WC—Co substrate, which assembly is subjected to processing conditions of extremely high pressure and high temperature (HPHT), where the solvent catalyst promotes desired inter-crystalline diamond-to-diamond bonding and, also, provides a binding between polycrystalline diamond body and substrate support. In another example, PDC cutter is formed by placing diamond powder without a catalyst material on the top of substrate containing a catalyst material (e.g. WC—Co substrate or WC—Co substrate and an additional thin cobalt disk facing the diamond powder). In this example, necessary cobalt catalyst material is supplied from the substrate and melted cobalt is swiped through the diamond powder during the HPHT process. In still another example, a hard polycrystalline diamond composite is fabricated by forming a mixture of diamond powder with silicon powder and mixture is subjected to HPHT process, thus forming a dense polycrystalline compact where diamond particles are binded together by newly formed SiC material.

Abrasion resistance of polycrystalline diamond composites and PDC cutters can be determined mainly by the strength of bonding between diamond particles (e.g. cobalt catalyst), or, in the case when diamond-to-diamond bonding is absent, by foreign material working as a binder (e.g. SiC binder), or in still another case, by both diamond-to-diamond bonding and foreign binder. Presence of catalyst inside the polycrystalline diamond body of PDC cutter promotes the degradation of cutting edge of the cutter during the cutting process, especially if the edge temperature reaches a high enough critical value. Probably, this cobalt driven degradation is caused by large difference in thermal expansion between diamond and catalyst (e.g. cobalt metal), and also by catalytic effect of cobalt on diamond graphitization. Removal of catalyst from the polycrystalline diamond body of PDC cutter, for example by chemical etching in acids, leaves interconnected network of pores and a residual catalyst (up to 10 vol %) trapped inside the polycrystalline diamond body. It has been demonstrated in previous art [GE patent] that removal of cobalt from PDC cutter significantly improves its abrasion resistance. Also it follows that a thicker cobalt depleted layer near the cutting edge provides better abrasion resistance of the PDC cutter than a thinner cobalt depleted layer. Thus, one traditional way to improve the performance of PDC cutter is to provide a thicker cobalt depleted layer near the cutting edge by more efficient chemical etching or other treatment.

Further improvement in PDC cutter performance is limited by the fact that a porous polycrystalline diamond material, left after removal of cobalt metal, has a hardness (typically 50-60 GPa), which is inferior to the hardness of dense, porous free polycrystalline diamond (typically 70-100 GPa). Direct attachment of dense polycrystalline layer to WC—Co substrate by brazing or by HPHT process did not provide a cuter whose performance in earth drilling applications is superior to conventional PDC cutters.

Therefore, there is a need for new approaches to the fabrication of polycrystalline composites and compacts with better performance.

### SUMMARY OF THE INVENTION

In one embodiment of the present invention, a cutting element includes: a substrate; a first polycrystalline diamond volume containing a catalyst material, and the first polycrystalline diamond volume is bonded to the abovementioned substrate; and a second diamond or diamond like volume being, formed predominantly from carbon atoms and is free of catalyst materials, wherein the second diamond or diamond like volume is adjacent to a working surface of cutting element, and this the second diamond or diamond like volume is bonded to the first polycrystalline diamond volume.

In another embodiment, a first polycrystalline diamond volume includes a first region reach in catalyst and a second region significantly depleted in catalyst material, wherein a first region is bonded to substrate and a second region is bonded to a second diamond or diamond like volume.

In still another embodiment a cutting element includes: a substrate; a first polycrystalline diamond volume bonded to the substrate along an interface; and a second diamond or diamond like volume adjacent to a working surface opposite the interface wherein the first polycrystalline diamond volume is sandwiched between the substrate and the second diamond or diamond like volume; wherein the first polycrystalline diamond volume comprises: an outer peripheral upper surface and an outer peripheral side surface, wherein the first polycrystalline diamond volume comprises the first region rich in catalyst and the second region significantly depleted in catalyst material, wherein the first region is bonded to the substrate and the second region is bonded to the second diamond or diamond like volume; wherein the second diamond or diamond like volume is adjacent to the working surface, wherein the second volume is formed predominantly from carbon atoms and is free of catalyst materials.

In still another embodiment of the present invention, a cutting element includes: a substrate and a volume of superabrasive material bonded to substrate and having an exterior surface that directly contacts the working material to cut, drill or machine; wherein the volume of superabrasive material comprises at least 3 regions extending from the exterior surface inside the superabrasive volume in the following order, as it counted from the exterior surface: a diamond or diamond like region formed predominantly from carbon atoms and free of catalyst materials, a polycrystalline diamond compact region significantly depleted in catalyst material, and a polycrystalline diamond compact region rich in catalyst material, wherein the later region is directly bonded to the substrate.

In still another embodiment of the present invention, a cutting element includes: a substrate; a first polycrystalline diamond volume bonded to substrate along an first interface; a second barrier volume of hard material bonded to first volume along a second interface which opposite a first interface; and a third diamond or diamond like volume bonded to second volume along a third interface which opposite the second interface, wherein a third volume is adjacent to the working surface of cutting element that directly contacts the working material to cut, drill or machine; wherein a second volume is sandwiched between a first and a third volumes. Abovementioned volumes may have the following composition: a first polycrystalline diamond volume contains a catalyst material; a second barrier volume comprises hard materials, including carbides (e.g. WC, TiC, NbC, etc.) or composites (e.g polycrystalline diamond composites, etc.), essentially free of catalyst material (e.g. Group VIII metals like Fe, Co, Ni, etc.); and a third diamond or diamond like volume is formed predominantly from carbon atoms and is free of catalyst materials.

In still another embodiment of the present invention, a cutting element includes: a first polycrystalline diamond composite volume and a second diamond or diamond like volume adjacent to the working surface that directly contacts the working material to cut, drill or machine; wherein a first polycrystalline diamond compact volume contains a binding material, and a second diamond or diamond like volume is formed predominantly from carbon atoms; wherein a second volume is bonded to a first volume.

Abovementioned diamond or diamond like volume or region is formed predominantly from carbon atoms and is completely free of catalyst materials; the volume or region may comprise one or more layers of diamond or diamond like materials; wherein the diamond materials include at least one of polycrystalline diamond; nanocrystalline diamond; ultrananocrystalline diamond; nanostructured diamond representing an amorphous carbon bulk with embedded diamond nanocrystals; hard tetrahedral amorphous carbon t-C; and amorphous carbon a-C.

In another exemplary embodiment, a method of growing a continuous diamond layer on a PDC cutter includes: machining the cutter to desired shape; cleaning the surface of cutter by sand blasting; removing the catalyst from the predetermined portion of surface of the cutter to a necessary depth by using suitable treatment; cleaning the cutter from treatment debris; placing the cutter on a holder inside the plasma vapor deposition reactor suitable for diamond coating; plasma etching the surface layer of the cutter using a first mixture of oxygen, hydrogen and argon feed gases; coating the cutter with a first layer of diamond using a second mixture of feed gases comprising methane and hydrogen, and maintaining the surface temperature of the cutter at a predetermined temperature for a period of time sufficient to form a first diamond layer; coating the cutter with a second layer of nanodiamond by adding an amount of nitrogen to the feed-gas mixture to provide the ratio of nitrogen to methane of about 10%, and maintaining the surface temperature of the cutter at a predetermined temperature for a period of time sufficient to form a second diamond layer.

In still another exemplary embodiment, a method of growing a continuous diamond layer on a polycrystalline diamond composite cutter includes: machining the cutter to desired shape; cleaning the surface of cutter by sand blasting; placing the cutter on a holder inside the plasma vapor deposition reactor suitable for diamond coating; plasma etching the surface layer of the cutter using a first mixture of oxygen, hydrogen and argon feed gases; coating the cutter with a first layer of diamond using a second mixture of feed gases comprising methane and hydrogen, and maintaining the surface temperature of the cutter at a predetermined temperature for a period of time sufficient to form a first diamond layer; coating the cutter with a second layer of nanodiamond by adding an amount of nitrogen to the feed-gas mixture to provide the ratio of nitrogen to methane of about 10%, and maintaining the surface temperature of the cutter at a predetermined temperature for a period of time sufficient to form a second diamond layer.

In yet another exemplary embodiment, A method of growing a continuous diamond layer on a cutter, includes: cleaning a surface of the cutter by sand blasting; removing a catalyst from the surface layer of the cutter; placing the catalyst removed cutter on a holder of a plasma vapor deposition reactor suitable for diamond coating; plasma etching the surface layer of the cutter using a first mixture of oxygen, hydrogen and argon feed gases; coating the cutter with a first layer of diamond using the deposition reactor using a second mixture comprising of about 4 vol % methane and hydrogen, and maintaining the surface temperature of the cutter at a first predetermined temperature for a period of time sufficient to form a first diamond layer; coating the cutter with a second layer of nanodiamond by adding an amount of nitrogen to the feed-gas mixture to provide the ratio of nitrogen/methane is about 10%, and maintaining the surface temperature of the cutter at a second predetermined temperature for a period of time sufficient to form a second diamond layer.

### BRIEF DESCRIPTION OF THE DRAWINGS

The foregoing summary, as well as the following detailed description of the embodiments, will be better understood when read in conjunction with the appended drawings. It should be understood that the embodiments depicted are not limited to the precise arrangements and instrumentalities shown.

FIG. 1 is schematic perspective view of a common cylindrical shape PDC cutter blank produced in a HPHT process;

FIG. 2 is a schematic cross-sectional view of a machined a machined PDC cutter comprising a polycrystalline diamond composite volume, a working surface, that includes a planar upper surface, a chamfer, and a side surface of PDC cutter;

FIG. 3 is a schematic cross-sectional view of a treated PDC comprising a volume depleted in cobalt, an outer peripheral upper surface, chamfer, and an outer peripheral side surface of the polycrystalline diamond composite volume.

FIG. 4A is a schematic cross-sectional view of PDC cutter coated with a volume of diamond or diamond like material which is extended along the outer peripheral side surface of the PDC cutter but does not reach the border of the volume depleted in catalyst.

FIG. 4B is a schematic cross-sectional view of PDC cutter coated with a volume of diamond or diamond like material which is extended along the outer peripheral side surface of the PDC cutter and reaches the border of the volume depleted in catalyst.

FIG. 4C is a schematic cross-sectional view of PDC cutter coated with a volume of diamond or diamond like material which is extended along the outer peripheral side surface of the PDC cutter and reaches to the interface between the polycrystalline volume of PDC cutter and substrate.

FIG. 4D is a schematic cross-sectional view of PDC cutter coated with a volume of diamond or diamond like material the border of this volume may does not extend to the side surface.

FIG. 4A. is a schematic partial cross-sectional view of a diamond coating volume representing two diamond layers of two different types;

FIG. 4B. is a schematic partial cross-sectional view of a diamond coating volume representing alternating two different types of diamond layers;

FIG. 4C. is a schematic partial cross-sectional view of a diamond coating volume representing three diamond layers of three different types;

FIG. 5 is a schematic partial cross-sectional view of a cutting element comprising a substrate, a polycrystalline diamond compact volume, which does not contain a catalyst or any transition metal, and volume of diamond or diamond like material bonded to substrate along an interface.

FIG. 6A is a schematic partial cross-sectional view of a diamond or diamond like volume comprising two layers of different diamond materials.

FIG. 6B is a schematic partial cross-sectional view of a diamond or diamond like volume comprising alternating layers of two different diamond materials.

FIG. 6C is a schematic partial cross-sectional view of a diamond or diamond like volume comprising three layers of three different diamond materials.

FIG. 7A is a schematic partial cross-sectional view of a cutting element comprising a polycrystalline diamond composite volume a diamond or diamond like volume, which coats one or several parts of the surface of polycrystalline diamond composite volume.

FIG. 8 is a schematic flow diagram illustrating a multi-step method of making a PDC cutter coated with diamond layers according to an exemplary embodiment;

FIG. 9 shows a VTL-c abrasion test results for type I coated and uncoated PDC cutters plotted as dependence of wear volume of cutter versus removed volume of rock;

FIG. 10 shows a VTL-c abrasion test results for high abrasion resistance type II coated and uncoated PDC cutters plotted as dependence of wear volume of cutter versus removed volume of rock; and

FIG. 11 shows a VTL-c abrasion test results for type III coated and uncoated diamond composite cutters plotted as dependence of wear volume of the cutter versus removed volume of the rock.

### DETAILED DESCRIPTION

Disclosed below exemplary embodiments provides an improved cutting element, such as diamond coated a polycrystalline diamond composite or PDC cutter, suitable for use in drilling and machining applications. Coating of polycrystalline diamond composite or PDC cutter with one or several layers of dense and hard diamond materials may have higher hardness and abrasion resistance compared to uncoated diamond cutting elements and improve the performance of coated cutting elements. The improvement in performance of diamond coated PDC cutter may also partially contribute from the effect of its better thermal stability, arising from inherent thermal stability of diamond coating originating from the homogeneity of its elemental composition, containing predominantly carbon and free of catalyst material by its nature. The addition of diamond coating may increase the effective thickness of the surface layer with low catalyst content.

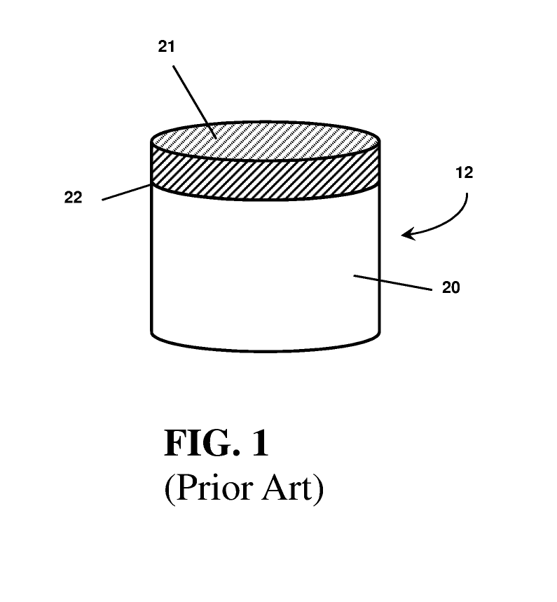

As shown in FIG. 1 shows schematic perspective view of a common cylindrical shape PDC cutter blank 12 produced in a HPHT process with a catalyst, and used here for further diamond coatings. Common PDC cutter blank 12 comprises: a substrate 20, which is made of hard metal, alloy, or composite, and most typically of cemented carbide or cobalt sintered tungsten carbide (WC—Co); and a polycrystalline diamond composite volume 21, rich in catalyst, as it was left after the HPHT process, and attached or joined coherently to the substrate along the interface 22. Very often, such catalyst as cobalt metal or its alloys may be present as a diamond bond forming aid in HPHT manufacture of the polycrystalline diamond volume 21. PDC cutter blank may be later machined to desired shape.

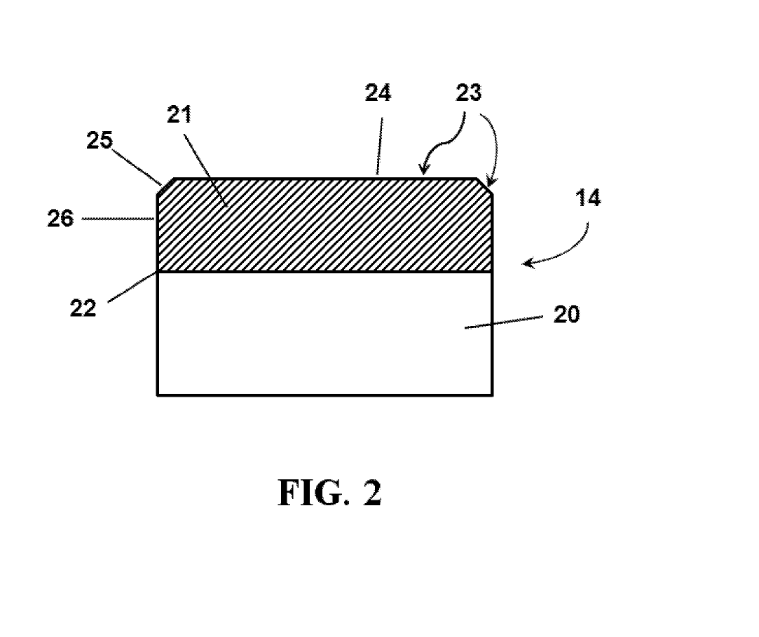

FIG. 2 shows an example embodiment of a machined PDC cutter 14 comprising a working surface 23 that includes a planar upper surface 24, a chamfer 25, and a side surface 26. As it is appreciated, the shape of PDC cutter described here does not limit the scope of current disclosure and PDC cutters with a variety of shapes may be coated with diamond materials according to the current disclosure.

It is well-known to those skilled in the art of diamond coatings that the process of coating different substrates by a vacuum deposition gives desired results only when transition metals, such as Fe, Co, Ni, are substantially removed from the substrate surface. It has been demonstrated that the presence of transition metals during the vacuum deposition promotes the formation of soft Sp² type carbons, e.g. black carbon, carbon nanotubes, buckyballs, graphenes, etc., instead of growing of Sp³ type diamond, resulting in pure adhesion of a diamond coating to the substrate.

Subsequently, prior to vapor phase deposition of diamond coatings is commonly preceded by preliminary treatment of the coated substrate surface, aimed at removal or blocking of transition metals. For example, before CVD diamond coating of cobalt cemented WC—Co compacts, it is common to treat the compact in an acid solution to etch cobalt away from the surface. Also cobalt was removed from the surface of WC—Co compact by thermal treatment, e.g. by forming the large surface grains of WC.

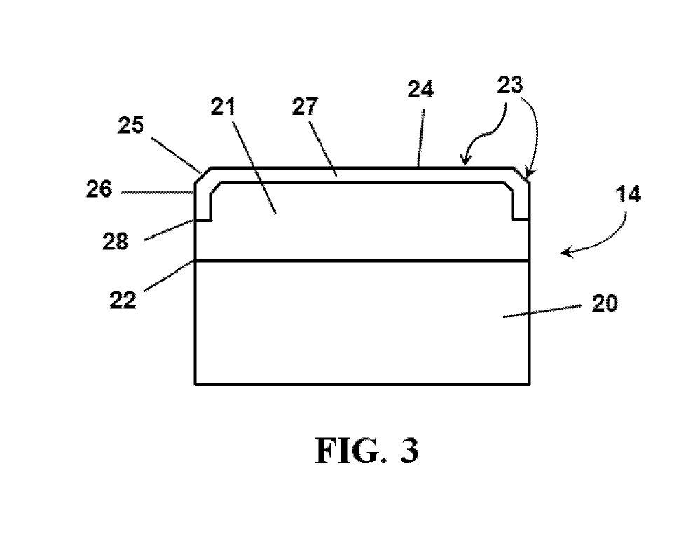

Thus, in an exemplary embodiment described here, the surface of machined PDC cutter 14 was treated in a mixture of acids in order to remove a surface layer of a catalyst and prepare cutter for diamond coating. Schematic cross-section of a treated PDC cutter 14 is shown FIG. 3. Cutter 14 may comprise: a volume 27 depleted in cobalt to a necessary one or several depths from, correspondently: an outer peripheral upper surface 24, chamfer 25, or an outer peripheral side surface 26 of the polycrystalline diamond composite volume 21 rich in catalyst, wherein volume 27 extends along the side surface 26 to a border 28 with volume 21, but does not reach the interface 22 with the substrate 20; a working surface 23 that includes a planar upper surface 24 and a chamfer 25. In particular cases, a volume 27 may extend away from an upper surface 24 to a first predetermined depth, from a chamfer 25 to a second predetermined depth, and from a side surface 26 to a third predetermined depth. The determination of necessary depletion depth may be based on how such depletion depth influences the quality of subsequent diamond coating, e.g. its adhesion to the substrate, etc., and finally the performance of coated cutter.

For example, each depletion depth, as they were described above, may be from about 10 μm to about 500 μm, or it could be from about 2 μm to about 60 μm, for example. Also, for example, a third depletion depth may constitute of at least half of the overall thickness of the polycrystalline diamond volume 21, but stops short of the interface 22 by at least about 500 μm, for example.

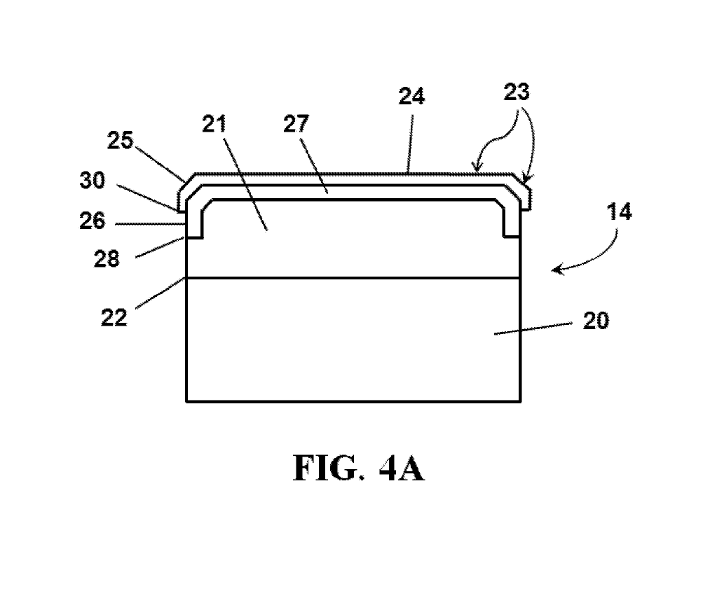

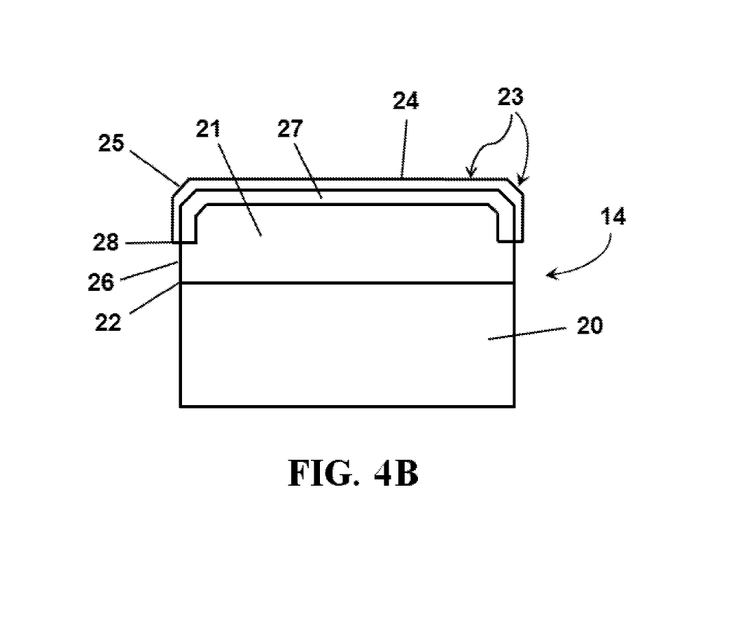

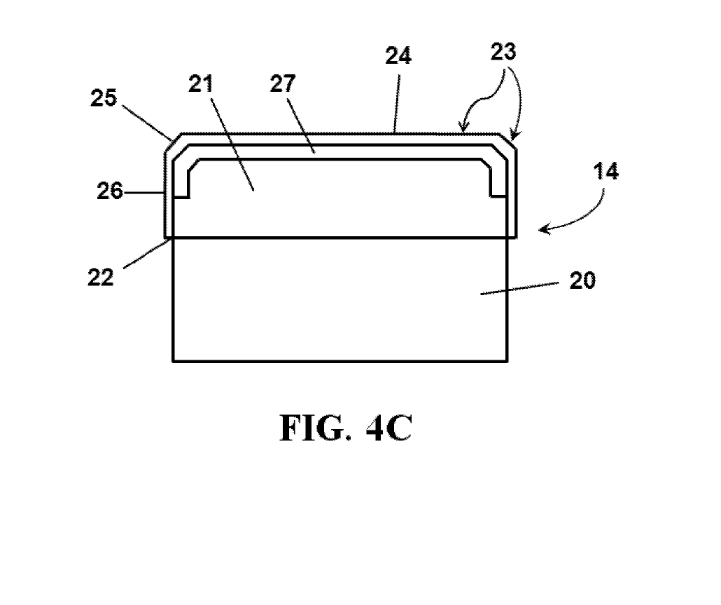

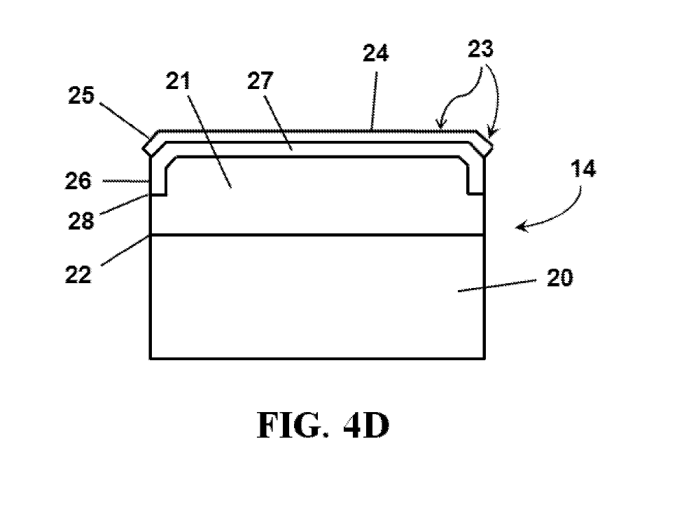

Treated PDC cutter 14 was cleaned in boiled water and placed on a holder inside a chamber suitable for vacuum diamond coating, such as a chemical vapor deposition (CVD), for example. CVD techniques suitable for current disclosure may include, but not limited to, microwave plasma CVD, hot filament CVD, DC plasma CVD, etc. PDC cutter 14 coated with a one or more layers of diamond material comprising a volume 29 is shown in FIG. 4A. Each diamond layer may be one of the following diamond types: a polycrystalline diamond; a nano-crystalline diamond; an ultra nanocrystalline diamond; a nanostructured diamond, representing an amorphous carbon bulk with embedded diamond nanocrystals (typically 10-80 vol %), wherein diamond nanocrystals are not bonded to each other but instead are bonded by amorphous carbon; a hard tetrahedral amorphous carbon t-C; and an amorphous carbon a-C. Different types of diamond may also include above mentioned diamond types additionally doped with small molar amounts of such elements as N, B, P, Si, S. Diamond layers may be all of different diamond types or several (two or more) diamond types may alternate each other. Diamond layer may be any suitable combination of layers of different diamond types.

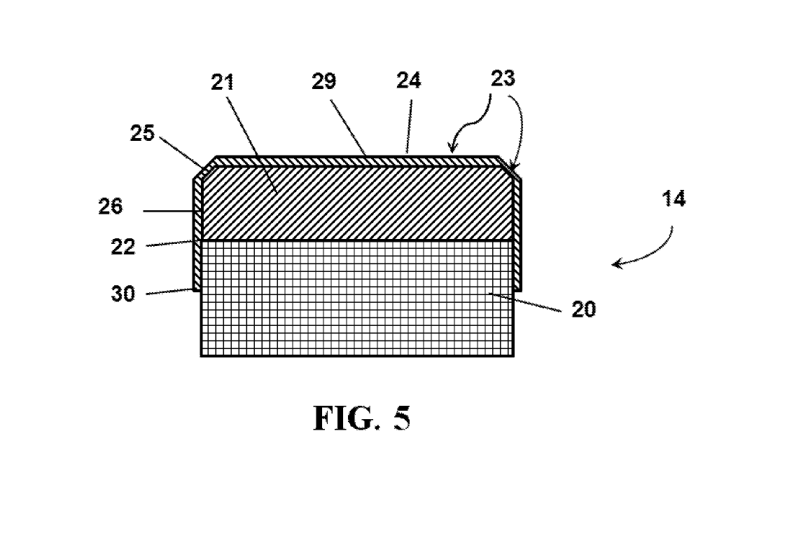

An exemplary embodiment may provide a high abrasion resistance cutter suitable for use in drilling and machining applications. The thickness of diamond coating in the diamond volume 29 (shown in FIG. 5) on PDC cutter may be about 5 μm to about 2000 μm or more, for example. In one exemplary embodiment, shown in FIG. 4A, the diamond volume 29 (shown in FIG. 5) may extend along the outer peripheral side surface 26 of the PDC cutter down to its border 30, but does not reach the border 28 of the volume 27 of depleted catalyst and the interface 22 with substrate 20.

In another exemplary embodiment, shown in FIG. 4B, the border 30 of diamond volume 29 may extend to the side surface 26 down to the border 28, but does not reach the interface 22. In still another exemplary embodiment, shown in FIG. 4C, the border 30 of diamond volume 29 may extend to the side surface 26 down to the interface 22. In yet another exemplary embodiment, shown in FIG. 4D, the border 30 of diamond volume 29 may not extend to the side surface 26 and coat only the upper surface 24 and the chamfer of cutter 14.

In still another exemplary embodiment, shown in FIG. 5, cutting element 44 may comprise: a substrate 20; a polycrystalline diamond compact volume 21, which does not contain a catalyst or any transition metal and volume 21 is bonded to substrate 20 along an interface 22; a diamond or diamond like volume 29, which coats the upper planar surface 24, chamfer 25, and the side surface 26 of a cutter 14.

As shown in FIGS. 4A-4D and FIG. 5, coating of PDC cutter with diamond volume 29 creates a second working surface 23, which includes a second planar upper surface 24 and a second chamfer 25, and the second working surface 23, in a significant extent, to the working surface 23 of uncoated cutter.

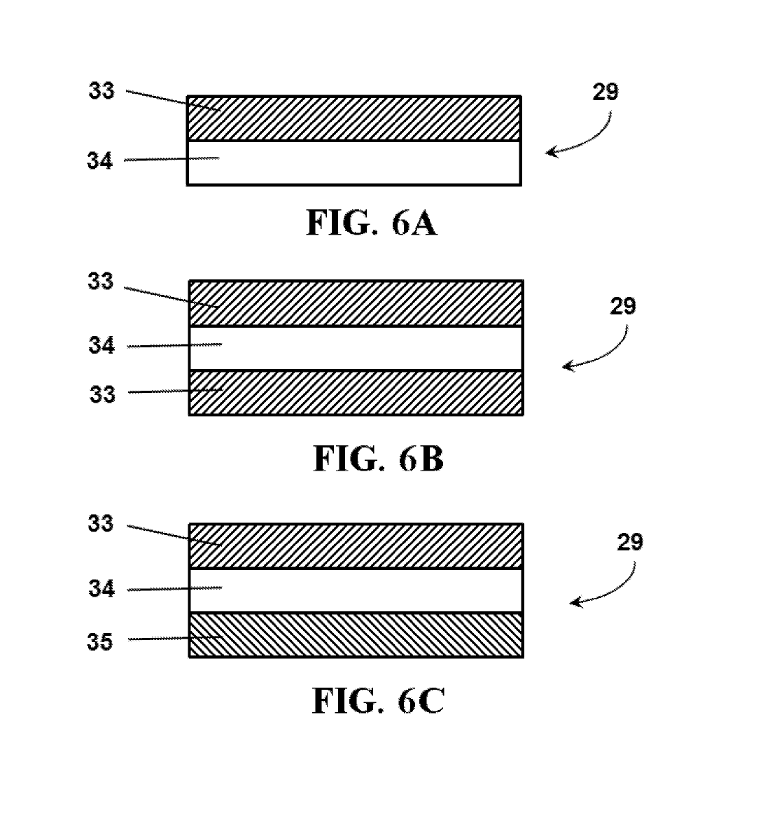

The diamond volume 29 may comprise one or more layers of diamond materials, as it is shown in FIGS. 6A-6C. In one embodiment, shown in FIG. 6A, diamond volume may comprise two layers of different types of diamond 33 and 34. More specifically, the layer 33 may be a coarse-sized polycrystalline diamond and the layer 33 may be a fine-sized polycrystalline diamond. Alternatively, the layer 33 may be a fine-sized polycrystalline diamond and the layer 34 may be a coarse-sized polycrystalline diamond. Also, one of those two layers may be, as it was described above, a nanocrystalline diamond, or ultra-nanocrystalline diamond, or nanostructured diamond comprising an amorphous carbon bulk with embedded nanocrystalline diamond, or an amorphous t-C, or an amorphous a-C carbon. In another exemplary embodiment, shown in FIG. 6B, diamond volume 29 may comprise three or more alternating layers of two different types of diamond, 33 and 34. In still another embodiment, shown in FIG. 6C, diamond volume may comprise three or more layers of absolutely different types of diamond, for example 33, 34, and 35.

As used herein, the terms “coarse-sized” and “fine-sized” diamond particles in two layers of diamond volume 29 do not necessary refer to a particular size or size range for the coarse-sized diamond particles and the fine-sized diamond particles. Instead, the terms “coarse-sized” and “fine-sized” refer to relative size differences between the coarse-sized diamond particles and the fine-sized diamond particles. The coarse-sized diamond particles may exhibit an average particle size (e.g., an average diameter) that may be about five times or more than an average particle size of the fine-sized diamond particles. For example, the coarse-sized diamond particles may exhibit an average particles size of at least about 100 μm (e.g., from about 100 μm to about 150 μm), and the fine-sized diamond particles may exhibit an average particle size of about 20 μm (e.g., from about 10 μm or about 30 μm). The fine-sized diamond particles may exhibit one or more selected sizes.

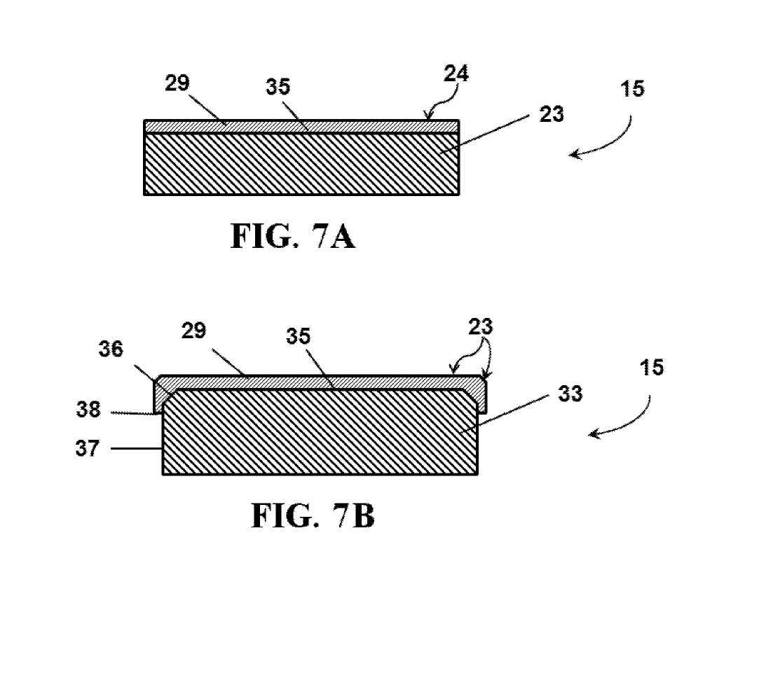

In still another embodiment, shown in FIGS. 7A and 7B, a cutting element 15 may comprise: a polycrystalline diamond composite volume 23 formed by bonding together individual diamond crystals by a binding material, wherein individual diamond crystals do not bond to each other in a significant extent and volume 23 does not contain a catalyst or any transition metal material; and a diamond volume 29, which coats one or several parts of the surface of volume 33 forming a working surface.

In one exemplary embodiment shown in FIG. 7A, a diamond volume 29 coats an upper planar surface 35 of a polycrystalline diamond composite volume 33 and forms a working surface 24. In another exemplary embodiment shown in FIG. 7B, a diamond volume 29 coats an upper planar surface 35, a chamfer 23, and a part of side surface 37 of volume 33 extending along the side surface 23 to the boundary 38, and forms a working surface 38.

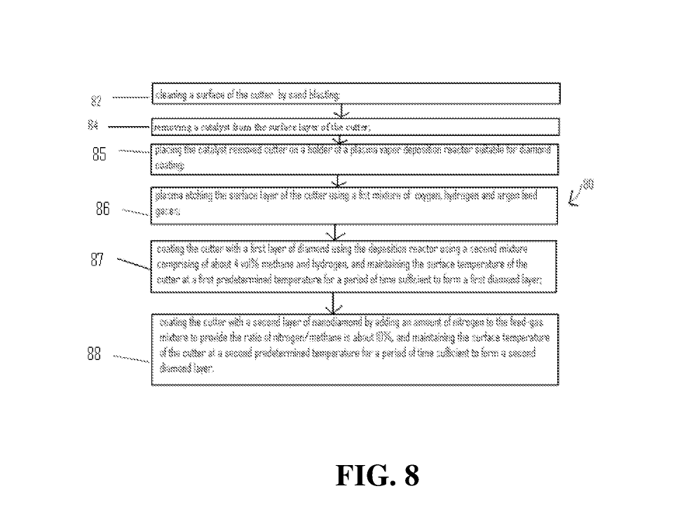

As shown in FIG. 8, an exemplary embodiment of a method 80 for growing a continuous diamond layer on a cutting element may comprise cleaning a surface of the cutter by sand blasting in a step 82. In a step 84, a catalyst, such as cobalt, may be removed from the surface layer of the cutter by chemical etching in an acid solution, for example. An exemplary embodiment of the method 80 further may comprise a step of placing the catalyst removed cutter on a holder of a plasma vapor deposition reactor suitable for diamond coating in a step 85; a step of plasma etching the surface layer of the cutter using a first mixture of oxygen, hydrogen and argon feed gases in a step 86; a step of coating the cutter with a first layer of diamond using the deposition reactor using a second mixture comprising of about 4 vol % methane and hydrogen, and maintaining the surface temperature of the cutter at a first predetermined temperature for a period of time sufficient to form a first diamond layer in a step 87; and coating the cutter with a second layer of nanodiamond by adding an amount of nitrogen to the feed-gas mixture to provide the ratio of nitrogen/methane is about 10%, and maintaining the surface temperature of the cutter at a second predetermined temperature for a period of time sufficient to form a second diamond layer in a step 88.

In a treatment step, a catalyst, such as cobalt metal or its alloys, may be removed from the surface layer of the cutter by chemical etching in an acid solution, for example, in a mixture of nitric and hydrofluoric acids, and subsequent cleaning of etching debris in water. An exemplary embodiment of the method 80 further may comprise the following subsequent steps: a step of placing the treated cutter on a holder inside a plasma vapor deposition reactor suitable for diamond coating; a step of plasma etching the surface layer of the cutter using a first feed-gas mixture of oxygen, hydrogen and argon; a step of coating the cutter with a first layer of diamond material inside the deposition reactor using a second feed-gas mixture comprising of about 1-20 vol % methane and 80-99 vol % hydrogen, and maintaining the surface temperature of the cutter at a first predetermined temperature for a sufficient period of time; and a step of coating the cutter with a second layer of nanodiamond in the feed-gas mixture obtained by adding an amount of nitrogen to the mixture used in step, such as to keep the ratio of nitrogen to methane concentrations of about 5-20, and maintaining the surface temperature of the cutter at a second predetermined temperature.

An exemplary embodiment of the method 80 may further comprise steps of shaping the cutter to a desired shape, for example making a chamfer; cleaning the catalyst removed cutter by boiling in pure deionized water. The first and second predetermined surface temperatures of the cutter during coating may be different or they may be the same, and also they to be lower than a one predetermined critical temperature. Several PDC cutters may be diamond coated simultaneously.

Coating with diamond materials may be achieved by using different chemical vapor deposition or physical vapor deposition techniques. Generally, diamond coating by different techniques is the result of the attachment to the coated surface carbon-containing species produced by the activation of carbon containing feed-gases or other materials, including solid or liquid carbon containing materials. In an exemplary embodiment coating by chemical vapor deposition with polycrystalline diamond may be achieved by using hydrogen and hydrocarbon feed-gas mixtures with different ratios of hydrocarbon to hydrogen, and coatings with nanodiamond or ultra-nanodiamond may be achieved by adding nitrogen to the hydrocarbon/hydrogen mixture or by using hydrocarbon/hydrogen/argon mixture, or other CVD coating process.

In an exemplary embodiment of current disclosure microwave plasma chemical vapor deposition reactor was used for diamond coating of PDC cutters and polycrystalline diamond substrates. In one aspect, the carbon-containing species produced by the disclosed plasma compositions can be deposited on the entire surface of the substrate. In another aspect, the carbon-containing species produced by the disclosed plasma compositions can be deposited on a portion of the surface of a substrate. In one aspect, a portion of the surface of the substrate can be covered with a “mask” prior to deposition; after deposition, the “mask” is removed, thereby providing a patterned film on the portion(s) of the surface of the substrate.

In an exemplary embodiment, a surface temperature of PDC cutter during diamond coating may be strictly controlled and may not exceed a critical surface temperature. The critical temperature value may be different from different types of cutters. In one exemplary embodiment, the surface temperature may be less than 650° C.; in another embodiment, the surface temperature may be less than 680° C.; and in still another embodiment, the surface temperature may be less than 1200° C. Surface temperature is continuously monitored during the deposition using optical pyrometer and adjusted to keep constant by changing microwave power or gas pressure. Critical surface temperature may be determined in abrasion resistance tests of coated cutters, e.g. in VTL-c tests.

In the exemplary embodiment, different types of hard and dense diamond materials may be coated on a top part and side parts of PCD cutter. The hard and dense diamond materials may be a polycrystalline diamond, nano-crystalline diamond, amorphous diamond with embedded (10-80%) of nano-crystalline diamond or their combination. In the case when PDC cutter represents a cutter with partial Co removal from the surface, the improvement in abrasion resistance of diamond coated cutter may be contributed by an increase of Co-free layer above the PDC bulk containing Co metal, and to the harder abrasion resistance of coated diamond layer compared to the PDC compact, for example.

The above-described diamond coated polycrystalline diamond composites and PDC cutters will be better understood with the reference to following examples.

### EXAMPLE 1

Cutting elements of type I were conventional commercially available PDC cutters. Those PDC cutters, representing a polycrystalline diamond volume bonded to a tungsten carbide cobalt substrate (WC—Co), were fabricated using the first HPHT process. After fabrication all PDC cutters were shaped by grinding and polishing to the cylindrical shape with diameter 13 mm and height 8 mm. The thickness of polycrystalline diamond table was about 2 mm. Finally, a chamfer (0.5 mm, 45°) was made on the top edge of polycrystalline diamond table of each cutter. After shaping completion, cutter's surface was cleaned by sand blasting using SiC bids. Before diamond coating all PDC cutters were chemically etched in acid solutions and then boiled in deionized water to clean from etching deposits. Different etching times provided PDC cutters with different Co depletion depths from the surface, such as from 10 to 200 μm deep. Co depletion depth was measured by SEM on sample cross-sections obtained after completion of coatings and subsequent abrasion tests. Several etched cutters were used for diamond coating and others were used as the references in abrasion tests.

Microwave plasma CVD reactor used for diamond coating was equipped with 2.45 GHz magnetron microwave source, cavity inside which plasma was maintained, water cooled stage inside the cavity for sample holder accommodation, gas system for feed-gas supply, and optical pyrometer for surface temperature measurements. Several PDC cutters were coated simultaneously. Chemically treated and cleaned cutters were placed on a sample holder inside the CVD reactor in such way that their surfaces were directly exposed to the plasma during coating. Gas pressure in the chamber was 50-200 mBar, and microwave power was 2-5 kW. Feed gases were supplied at 1000 sccm (hydrogen) and 50-100 sccm (methane) flow rates. In some experiments, addition of 5-50 sccm of nitrogen to the feed gas mixture was used to grow nanodiamond layers. Coating conditions were controlled by adjusting the gas pressure inside a bell-jar, microwave power, feed gas flow rates, and a holder spatial position inside the plasma. Surface temperature of cutters was controlled by optical pyrometer and kept constant using microwave power or gas pressure feedback.

Diamond coated PDC cutters were subjected to abrasion test, representing a standard vertical turret lather test using flushing water as a coolant (VTL-c). The PDC cutter was oriented at a 15° back rake angle against the surface of Barre Gray Granite rock wheel having a 1.82 m diameter. Such rock materials may comprise a compressive strength of about 200 MPa. The tested cutter traveled on the surface of the granite wheel while the cutting element was held constant at a 0.36 cm depth of cut and the feed was 0.36 mm/revolution.

It was found from VTL-c tests that the surface temperature of cutters, Tₛᵤᵣ during diamond growth has a dramatic effect on the performance of coated cutters. It was determined that there is a threshold temperature T_{crit}, which is different for different types of cutters. For example, T_{crit} could be 700° C. or 750° C. Above the critical temperature, the wear rate of coated PDC cutters in the abrasion test was worse than before coating and even experienced fast catastrophic failure when the temperature was more than 50° C. above the T_{crit}. It was found that Tₛᵤᵣ should be at least 20° C. less than T_{crit}.

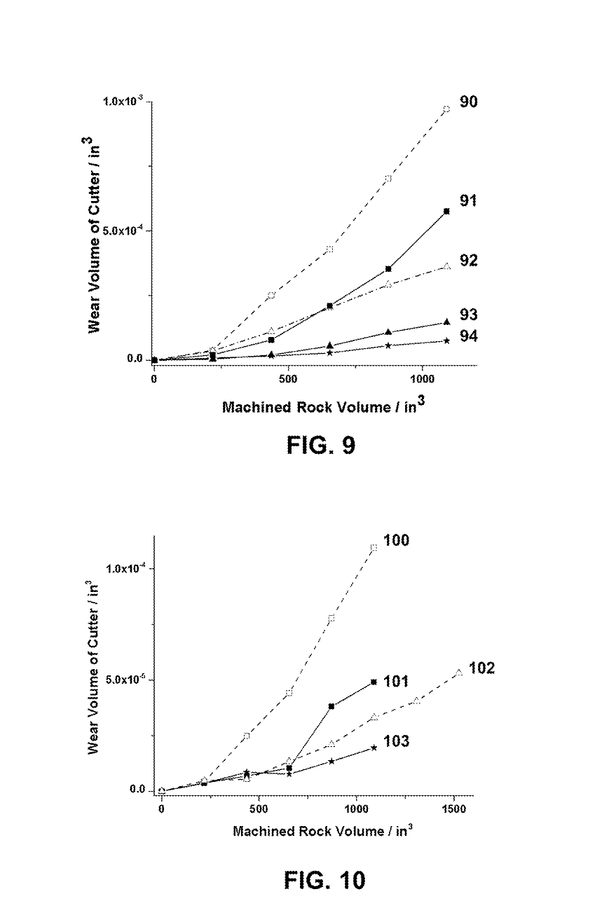

VTL-c abrasion testing results, plotted as dependence of wear volume of cutter versus removed volume of rock, are shown in FIG. 9. Solid lines represent diamond coated cutters and dashed lines represent uncoated cutters. It can be seen that, after machining a rock volume of 1090 in³, the wear of cutter with initial Co-depletion depth of 10 μm and coated with 50 μm of polycrystalline diamond (curve 91) is about 1.7 times lower than the wear of uncoated cutter with Co-depletion depth of 10 μm (curve 90). Such cutter, having only 60 μm thick thermally stable layer consisting of initial Co-depleted layer and diamond coating, performs almost like the uncoated cutter caving 200 μm Co-depletion depth (curve 92). Thus, the effect of coating PDC cutter with hard polycrystalline diamond layer significantly exceeds the trivial effect of increasing the thickness of thermally stable diamond layer by addition of diamond coating which is inherently thermally stable. The wear of cutter with deeper initial Co-depletion depth of 200 μm and coated with only 50 μm of polycrystalline diamond (curve 93) is 2.5 times lower than the wear of uncoated cutter with Co-depletion depth of 200 μm (curve 92). Thus again, the effect of coating PDC cutter with hard polycrystalline diamond layer significantly exceeds the cumulative effect of increasing the thickness of thermally stable diamond layer by addition of diamond coating, which in this case was increased insignificantly, from 200 μm to 250 μm. The wear of cutter with initial Co-depletion depth of 200 μm and coated with 2 layers of 50 μm of polycrystalline diamond and 55 μm of nanodiamond (total coating thickness is 115 μm) (curve 94) is about 5 times lower than the wear of uncoated cutter with Co-depletion depth of 200 μm (curve 92) and about 2 times lower than the wear of similar cutter coated with 50 μm of polycrystalline diamond (curve 92).

### EXAMPLE 2

Cutting elements of type II were abrasion resistance PDC cutters, fabricated using the second HPHT process. PDC cutters were treated and diamond coated in the same manner as it was described in the Example 1, and subsequently VTL-c tested on the same granite rock as Type I cutters, according to the testing procedures described in Example 1.

VTL-c abrasion testing results of Type II cutters, plotted as dependence of wear volume of cutter versus removed volume of rock, are shown in FIG. 10. Solid lines represent diamond coated cutters and dashed lines represent uncoated cutters. It is seen that, after machining a rock volume of 1090 in³, the wear of cutter with initial Co-depletion depth of 10 μm and coated with 50 μm of polycrystalline diamond (curve 101) is about 2.2 times lower than the wear of uncoated cutter with Co-depletion depth of 10 μm (curve 100). Such cutter, having only 60 μm thick thermally stable layer consisting of initial Co-depleted layer and diamond coating, performs close to the uncoated cutter having extra deep 400 μm Co-depletion depth (curve 102). The wear of cutter with initial Co-depletion depth of 60 μm and coated with only 50 μm of polycrystalline diamond (curve 103) is about the same or lower than the wear of deep 400 μm Co-depletion depth (curve 102). Thus, the effect of coating PDC cutter with hard polycrystalline diamond layer significantly exceeds the trivial effect of increasing the thickness of thermally stable diamond layer by addition of diamond coating which is inherently thermally stable.

### EXAMPLE 3

Cutting elements of type III, were polycrystalline diamond composites, fabricated in the third HPHT process by sintering of diamond powder with SiC binder. Type III cutters were stand-alone pieces, do not bound to other support or substrate. Type III cutters do not contain any transition metal or their compounds; thus they are inherently thermally stable. After fabrication all type III cutters were shaped by grinding and polishing to the cylindrical shape with diameter 13 mm and height 8 mm. Finally, a chamfer (0.5 mm, 45°) was made on the top edge of each cutter. After shaping completion, cutter's surface was cleaned by sand blasting using SiC bids and the cutters were placed on the sample holder inside the same microwave plasma CVD reactor as in Examples 1 and 2 for diamond coating. Type III cutters were coated with 50 μm of nanodiamond, using the coating conditions described in Example 2, and subsequently were VTL-c tested on the same granite rock as Type I and II cutters, according to the testing procedures described in Example 1.

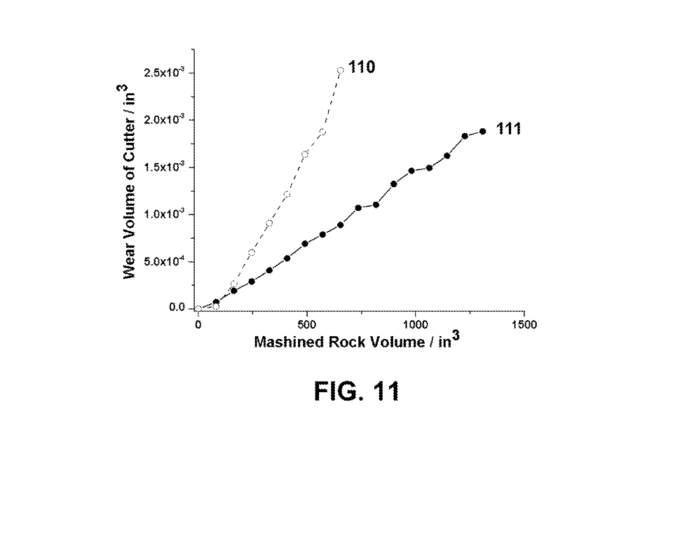

VTL-c abrasion testing results of type III cutters, plotted as dependence of wear volume of cutter versus removed volume of rock, are shown in FIG. 11. Solid line represent diamond coated cutter and dashed line represent uncoated cutter. It is seen that, after machining a rock volume of 650 in³, the wear of cutter coated with 50 μm of nanodiamond (curve 111) is about 2.8 times lower than the wear of uncoated cutter. Because type III cutter is made from an inherently thermally stable material, the effect of diamond coating was completely associated with the deposition of hard nanodiamond layer on the cutting surface and was not partly related to the improvement of thermal stability after coating, as it was with type I and II cutters. It was determined that maximum surface temperature of type III cutter during coating can be as high as 1100° C.

Although described in connection with preferred embodiments thereof, it will be appreciated by those skilled in the art that additions, deletions, modifications, and substitutions not specifically described may be made without departure from the spirit and scope of the invention as defined in the appended claims.

While reference has been made to specific embodiments, it is apparent that other embodiments and variations can be devised by others skilled in the art without departing from their spirit and scope. The appended claims are intended to be construed to include all such embodiments and equivalent variations.

What is claimed is:

1. A cutting element, comprising:
a substrate;
a first polycrystalline diamond volume containing a catalyst material, and the first polycrystalline diamond volume is bonded to the substrate; and
a second diamond or diamond like volume being formed predominantly from carbon atoms and free of catalyst materials, wherein the second diamond or diamond like volume is adjacent to a working surface of cutting element, and the second diamond or diamond like volume is bonded to the first polycrystalline diamond volume.

2. The cutting element of claim 1, wherein a first polycrystalline diamond volume comprises a first region rich in catalyst and a second region significantly depleted in catalyst material, wherein the first region in catalyst is bonded to the substrate and the second region is bonded to the second diamond or diamond like volume.

3. The cutting element of claim 1, wherein the second diamond or diamond like volume formed predominantly from carbon atoms comprises one or more layers of diamond or diamond like materials.

4. The cutting element of claim 1, wherein the catalyst material is present as a sintering aid in manufacture of the first polycrystalline diamond volume.

5. The cutting element of claim 1, wherein the substrate is a cemented carbide substrate.

6. The cutting element of claim 3, wherein the one or more layers of diamond or diamond like materials include at least one of polycrystalline diamond; nano-crystalline diamond; ultra nanocrystalline diamond; nanostructured diamond, amorphous carbon bulk with embedded diamond nanocrystals; hard tetrahedral amorphous carbon t-C; and amorphous carbon a-C.

7. The cutting element of claim 3, wherein the diamond or diamond like materials comprise diamond doped with such elements as N, B, P, Si, S.

8. A cutting element comprises:
a substrate;
a first polycrystalline diamond volume bonded to the substrate along an interface; and
a second diamond or diamond like volume adjacent to a working surface opposite the interface wherein the first polycrystalline diamond volume is sandwiched between the substrate and the second diamond or diamond like volume; wherein the first polycrystalline diamond volume comprises: an outer peripheral upper surface and an outer peripheral side surface, wherein the first polycrystalline diamond volume comprises the first region rich in catalyst and the second region significantly depleted in catalyst material, wherein the first region is bonded to the substrate and the second region is bonded to the second diamond or diamond like volume;
wherein the second diamond or diamond like volume is adjacent to the working surface, wherein the second volume is formed predominantly from carbon atoms and is free of catalyst materials.

9. The cutting element of claim 8, wherein the second diamond volume formed predominantly from carbon atoms and free of catalyst materials extends above the outer peripheral upper surface, and extends along the outer peripheral side surface of the first polycrystalline diamond volume away from the working surface toward the substrate.

10. The cutting element of claim 8, where the second diamond volume formed predominantly from carbon atoms and free of catalyst materials is limited to the outer peripheral upper surface of the first polycrystalline diamond volume.

11. The cutting element of claim 8, where the second diamond volume formed predominantly from carbon atoms and free of catalyst materials is limited to the working surface.

12. The cutting element of claim 8, where the second region significantly depleted in catalyst material extends away from the outer peripheral upper surface to a first predetermined depth and from the outer peripheral side surface to the second predetermined depth.

13. The cutting element of claim 8, wherein a second volume formed predominantly from carbon atoms comprises one or more layers of diamond or diamond like materials.

14. The cutting element of claim 12, wherein the diamond materials include at least one of polycrystalline diamond; nano-crystalline diamond; ultra nanocrystalline diamond; nanostructured diamond, amorphous carbon bulk with embedded diamond nanocrystals; hard tetrahedral amorphous carbon t-C; and amorphous carbon a-C.

15. The cutting element of claim 12, wherein the diamond materials comprise diamond doped with such elements as N, B, P, Si, S.

16. A cutting element comprises:
a first polycrystalline diamond composite volume, and
a second diamond or diamond like volume adjacent to the working surface that directly contacts the working material to cut, drill or machine; wherein
a first polycrystalline diamond composite volume comprises a binding material, and individual diamond crystals; and a second diamond or diamond like volume; wherein a second volume is bonded to a first volume.

17. The cutting element of claim 16, where the second diamond or diamond like volume is formed predominantly from carbon atoms.

18. The cutting element of claim 16, where a third volume comprises one or more layers of diamond or diamond like materials.

19. The cutting element of claim 16, wherein the diamond materials include at least one of polycrystalline diamond; nano-crystalline diamond; ultra nanocrystalline diamond; nanostructured diamond, amorphous carbon bulk with embedded diamond nanocrystals; hard tetrahedral amorphous carbon t-C; and amorphous carbon a-C.

20. The cutting element of claim 16, wherein the diamond materials comprise diamond doped with such elements as N, B, P, Si, S.

21. A method of growing a continuous diamond layer on a cutter, comprising:
cleaning a surface of the cutter by sand blasting;
removing a catalyst from the surface layer of the cutter;
placing the catalyst removed cutter on a holder of a plasma vapor deposition reactor suitable for diamond coating;
plasma etching the surface layer of the cutter using a first mixture of oxygen, hydrogen and argon feed gases;
coating the cutter with a first layer of diamond using the deposition reactor using a second mixture comprising of about 4 vol % methane and hydrogen, and maintaining the surface temperature of the cutter at a first predetermined temperature for a period of time sufficient to form a first diamond layer;
coating the cutter with a second layer of nanodiamond by adding an amount of nitrogen to the feed-gas mixture to provide the ratio of nitrogen/methane is about 10%, and maintaining the surface temperature of the cutter at a second predetermined temperature for a period of time sufficient to form a second diamond layer.

22. The method of claim 21, wherein plasma etching comprises at least one of microwave plasma etching, glow discharge, hot filament.

23. The method of claim 21, wherein the cutter is coated in chemical vapor deposition, physical vapor deposition.

24. The method of claim 21, further comprising shaping the cutter to a desired shape.

25. The method of claim 21, wherein the leaching the catalyst from the surface layer of the cutting element comprises chemical etching in an acid solution.

26. The method of claim 21 further comprising cleaning the catalyst removed cutter by boiling in pure water.

27. The method of claim 21, wherein the vapor deposition reactor is a chemical vapor deposition (CVD) reactor.

28. The method of claim 21 wherein the first and second pre-determined temperature is under a critical temperature.

30. The method of claim 28, wherein the critical temperature depends on a type of cutter.

31. The method of claim 28, wherein the first predetermined temperature is same as the second predetermined temperature.
